(19) United States
(12) Patent Application Publication
(10) Pub. No.: US 2026/0164547 A1
(43) Pub. Date: Jun. 11, 2026

(54) PRINTED CIRCUIT BOARD

(71) Applicant: SAMSUNG ELECTRO-MECHANICS CO., LTD., Suwon-si (KR)

(72) Inventors: Yong Duk LEE, Suwon-si (KR); Myong Keun JUNG, Suwon-si (KR); Kwang Jin KIM, Suwon-si (KR); Ki Ran PARK, Suwon-si (KR); Kyeong Yub JUNG, Suwon-si (KR); Jin Oh PARK, Suwon-si (KR); Ki Suk KIM, Suwon-si (KR)

(73) Assignee: SAMSUNG ELECTRO-MECHANICS CO., LTD., Suwon-si (KR)

(21) Appl. No.: 19/384,046

(22) Filed: Nov. 10, 2025

(30) Foreign Application Priority Data
Dec. 10, 2024 (KR) 10-2024-0182713

(51) Int. Cl. H05K 1/02; H05K 1/11

(52) U.S. Cl. CPC H05K 1/0298; H05K 1/115; H05K 2201/096

(57) ABSTRACT

A printed circuit board includes a first wiring portion having a first insulating body and a plurality of first wiring layers. An uppermost first wiring layer is embedded in an upper side of the first insulating body, with at least a portion of its upper surface exposed from the upper surface of the first insulating body. A second wiring portion is disposed on an upper side of the first wiring portion and includes a second insulating body covering at least a portion of the upper surface of the uppermost first wiring layer, and a plurality of second wiring layers. A minimum pitch of a wiring included in at least one of the second wiring layers is smaller than a minimum pitch of a wiring included in at least one of the remaining first wiring layers, excluding the uppermost first wiring layer, thereby enabling high-density wiring on a flat base.

### CROSS-REFERENCE TO RELATED APPLICATION(S)

This application claims the benefit of priority to Korean Patent Application No. 10-2024-0182713 filed on Dec. 10, 2024 in the Korean Intellectual Property Office, the disclosure of which is incorporated herein by reference in its entirety.

### TECHNICAL FIELD

The present disclosure relates to a printed circuit board.

Due to the high performance of semiconductor chips such as smartphone APs, server CPUs, and AI accelerators, demand for package substrates containing high-density circuits is expanding. Accordingly, the bump pitch is decreasing, and high-layer and large-area structures are required. In detail, to respond to the increasing number of input/output terminals, microcircuit implementation technology is becoming important.

### SUMMARY

An aspect of the present disclosure is to provide a printed circuit board that facilitates a microcircuit formation by securing excellent flatness and the like.

An aspect of the present disclosure is to provide a printed circuit board having a multilayer substrate structure of a coreless type.

An aspect of the present disclosure is to provide a printed circuit board in which costs may be reduced.

According to an aspect of the present disclosure, a wiring layer including an ETS pattern and an additional wiring layer are formed on a detach core, and then the laminate is detached, and a wiring layer including a microcircuit is further formed on the flat surface on which the ETS pattern is formed, and an additional wiring layer is formed on the opposite side as required, thereby implementing a multilayer substrate having a coreless structure.

According to an aspect of the present disclosure, a printed circuit board includes a first wiring portion including a first insulating body and a plurality of first wiring layers respectively disposed on a lower surface of or within the first insulating body, an uppermost first wiring layer of the plurality of first wiring layers being embedded in an upper side of the first insulating body, and at least a portion of an upper surface of the uppermost first wiring layer being exposed from an upper surface of the first insulating body; and a second wiring portion disposed on an upper side of the first wiring portion, and including a second insulating body covering at least a portion of the upper surface of the uppermost first wiring layer, and a plurality of second wiring layers respectively disposed on an upper surface of or within the second insulating body. A minimum pitch of a wiring included in at least one of the plurality of second wiring layers is smaller than a minimum pitch of a wiring included in at least one of remaining first wiring layers excluding the uppermost first wiring layer.

According to an aspect of the present disclosure, a printed circuit board includes a first wiring portion including a plurality of first insulating layers, a plurality of first wiring layers, and a plurality of first via layers, an uppermost first wiring layer of the plurality of first wiring layers being embedded in an upper side of an uppermost first insulating layer of the plurality of first insulating layers, and at least a portion of an upper surface of the uppermost first wiring layer being exposed from an upper surface of the uppermost first insulating layer; and a second wiring portion disposed on an upper side of the first wiring portion, and including one or more second insulating layers, one or more second wiring layers, and one or more second via layers. A first connection via included in each of the plurality of first via layers and a second connection via included in each of the one or more second via layers have side surfaces substantially tapered in opposite directions in a cross-section.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a cross-sectional view schematically illustrating an example of a printed circuit board; and

FIGS. 3 and 4 are cross-sectional views schematically illustrating a manufacturing example of the printed circuit board of FIG. 2.

### DETAILED DESCRIPTION

Hereinafter, the present disclosure will be described with reference to the attached drawings. In the drawings, the shapes and sizes of elements may be exaggerated or reduced for clearer explanation.

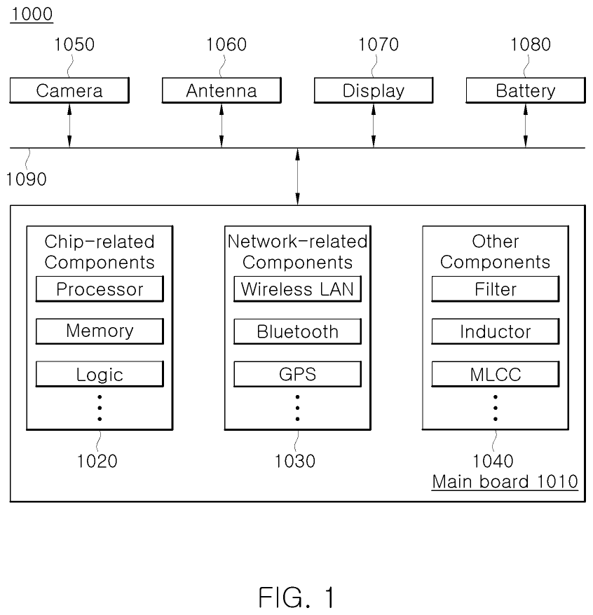

FIG. 1 is a block diagram schematically illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to other electronic components to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, but may also include other types of chip related electronic components. In addition, the chip related components 1020 may also be combined with each other. The chip-related component 1020 may be in the form of a package including the aforementioned chip or electronic component.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+ (HSPA+), high speed downlink packet access+ (HSDPA+), high speed uplink packet access+ (HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, but may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive elements in the form of chip components used for various other purposes, and the like. In addition, other components 1040 may also be combined with the chip related components 1020 and/or the network related components 1030.

Depending on a type of the electronic device 1000, the electronic device 1000 may include other electronic components that may or may not be physically or electrically connected to the mainboard 1010. These other electronic components may include, for example, a camera module 1050, an antenna module 1060, a display device 1070, a battery 1080, and the like, but are not limited thereto. These other electronic components may be an audio codec, a video codec, a power amplifier, a compass, an accelerometer, a gyroscope, a speaker, a mass storage unit (for example, a hard disk drive), a compact disc (CD) drive, a digital versatile disc (DVD) drive, or the like. In addition, these other electronic components may also include other electronic components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, a server, or the like. However, the electronic device 1000 is not limited thereto, but may be any other electronic device that processes data.

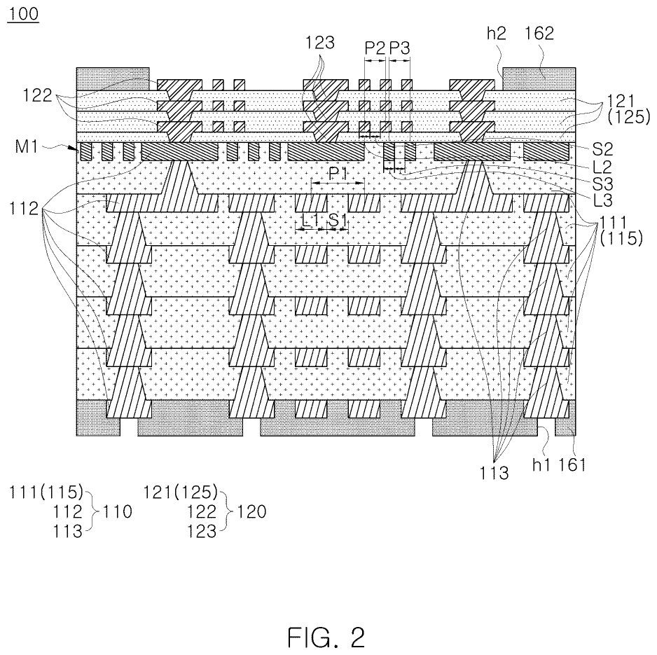

FIG. 2 is a cross-sectional view schematically illustrating an example of a printed circuit board.

Referring to the drawing, a printed circuit board 100 according to an example may include a first wiring portion 110 and a second wiring portion 120 disposed on an upper side of the first wiring portion 110. The first wiring portion 110 may include a first insulating body 115 and a plurality of first wiring layers 112 disposed on a lower surface of or within the first insulating body 115. Among the plurality of first wiring layers 112, an uppermost first wiring layer M1 may be embedded in an upper side of the first insulating body 115, and at least a portion of an upper surface of the uppermost first wiring layer M1 may be exposed from an upper surface of the first insulating body 115. For example, the uppermost first wiring layer M1 may be an Embedded Trace Substrate (ETS) pattern. The second wiring portion 120 may include a second insulating body 125 covering at least a portion of the upper surface of the uppermost first wiring layer M1, and a plurality of second wiring layers 122 respectively disposed on the upper surface of or within the second insulating body 125. The second wiring portion 120 may include a relatively high-density wiring area compared to the first wiring portion 120, except for the uppermost first wiring layer M1.

In this manner, in the printed circuit board 100 according to an example, the uppermost first wiring layer M1 of the first wiring portion 110 may be an ETS pattern layer that may form a microcircuit and have excellent flatness, and thus the second wiring portion 120 formed thereon may be formed at a high density. For example, a microcircuit may be easily formed in the second wiring portion 120. For example, a plurality of second wiring layers 122 included in the second wiring portion 120 may be used as a 2.1D Redistribution Layer (RDL) for connecting a chip and a substrate. In addition, when forming the second wiring portion 120, the build-up may be further performed downwardly of the first wiring portion 110, and thus, build-up on both sides may be possible. This structure may be manufactured in a coreless form. For example, the first and second wiring portions 110 and 120 may each have a coreless substrate structure. Therefore, the number of layers may be reduced, thereby reducing the overall package thickness, and it may easily respond to high-layering and large-area expansion. Therefore, since die-to-die connection becomes possible at the substrate level, process difficulty, cost, and the like may be reduced.

For example, a minimum pitch P2 of the wiring included in at least one of the plurality of second wiring layers 122 may be smaller than a minimum pitch P1 of the wiring included in at least one of the remaining first wiring layers 112 excluding the uppermost first wiring layer M1. For example, the minimum pitch P2 of the wiring included in each of the plurality of second wiring layers 122 may be smaller than the minimum pitch P1 of the wiring included in each of the remaining first wiring layers 112. In addition, the minimum pitch P3 of the wiring included in the uppermost first wiring layer M1 may be smaller than the minimum pitch P1 of the wiring included in each of the remaining first wiring layers 112. Meanwhile, the pitch may be the distance between the center lines of adjacent wirings, and the wiring may be a line, a trace, or the like.

In addition, a minimum linewidth L2 of the wiring and a minimum spacing S2 between the wirings included in at least one of the plurality of second wiring layers 122 may be smaller than a minimum linewidth L1 of the wiring and a minimum spacing S1 between the wirings included in at least one of the remaining first wiring layers 112. For example, the minimum linewidth L2 of the wiring and the minimum spacing S2 between the wirings included in each of the plurality of second wiring layers 122 may be smaller than the minimum linewidth L1 of the wiring and the minimum spacing S1 between the wirings included in each of the remaining first wiring layers 112. In addition, a minimum linewidth L3 of the wiring and the minimum spacing S3 between the wirings included in the uppermost first wiring layer M1 may be smaller than the minimum linewidth L1 of the wiring and the minimum spacing S1 between the wirings included in each of the remaining first wiring layers 112. Meanwhile, the linewidth and spacing may be L(line)/S(space), and the wiring may be a line, trace, or the like.

In addition, the minimum insulation distance between the plurality of second wiring layers 122 may be smaller than the minimum insulation distance between the plurality of first wiring layers 112, and the thickness of the second insulating body 125 may be thinner than the thickness of the first insulating body 115.

In addition, the first wiring portion 110 may further include a plurality of first via layers 113 that are respectively disposed within the first insulating body 115 and electrically connect the plurality of first wiring layers 112 to each other. In addition, the second wiring portion 120 may further include a plurality of second via layers 123 that are respectively disposed within the second insulating body 125 and electrically connect the plurality of second wiring layers 122 to each other. Among the plurality of second via layers 123, the lowermost second via layer 123 may electrically connect the lowermost second wiring layer 122 among the plurality of second wiring layers 122 to the uppermost first wiring layer M1. The first and second connection vias included in the plurality of first and second via layers 113 and 123, respectively, may have side surfaces that are substantially tapered in opposite directions when viewed in a cross-section. For example, the first connection via included in each of the plurality of first via layers 113 may have a side surface that is substantially tapered such that a width of a lower end portion is wider than a width of an upper end portion when viewed in a cross-section. In addition, the second connection via included in each of the plurality of second via layers 123 may have a side surface that is substantially tapered such that a width of an upper end portion is wider than a width of a lower end portion when viewed in a cross-section. For example, the first and second wiring portions 110 and 120 of the above-described structure may have a plurality of first and second via layers 113 and 123 having such a tapered structure.

Meanwhile, a first passivation layer 161 having a plurality of first openings h1 exposing at least a portion of the lowermost first wiring layer 112 among the plurality of first wiring layers 112 may be disposed on the lower surface of the first insulating body 115. In addition, a second passivation layer 162 having one second opening h2 exposing at least a portion of the uppermost second wiring layer 122 among the plurality of second wiring layers 122 may be disposed on the upper surface of the second insulating body 125. The plurality of first openings h1 may expose at least portions of the plurality of respective wiring patterns included in the lowermost first wiring layer 112. The second opening h2 may expose together at least portions of the plurality of respective wiring patterns included in the uppermost second wiring layer 122. For example, solder balls and the like may be disposed on the wiring patterns respectively exposed through the plurality of first openings h1, and thereby the printed circuit board 100 may be mounted on another substrate, such as a main board. In addition, solder bumps and the like may be disposed on the respective wiring patterns exposed through the second opening h2, and thereby electronic components, such as semiconductor chips, may be mounted on the printed circuit board 100.

Hereinafter, components of a printed circuit board 100 according to an example will be described in more detail with reference to the drawings.

The first and second insulating bodies 115 and 125 may each include an organic insulating material. The organic insulating material may include a thermosetting resin such as an epoxy resin, a thermoplastic resin such as a polyimide, or an inorganic filler, an organic filler, and/or glass fiber together with these insulating resins. For example, the first and second insulating bodies 115 and 125 may include an insulating material including an insulating resin and an inorganic filler, such as an Ajinomoto build-up film (ABF), but are not limited thereto, and may also include a photoimageable dielectric material (PID), or the like. The first and second insulating bodies 115 and 125 may include a plurality of first and second insulating layers 111 and 121, respectively. The plurality of first insulating layers 111 may have distinct boundaries from each other, or may be integrated with each other so that the boundaries are not distinct. The plurality of second insulating layers 121 may have distinct boundaries from each other, or may be integrated with each other so that the boundaries are not distinct. If necessary, the second insulating body 125 may include one or more second insulating layers 121.

The plurality of first and second wiring layers 112 and 122 may each include a metal. The metal may include copper (Cu), aluminum (Al), silver (Ag), tin (Sn), gold (Au), nickel (Ni), lead (Pb), titanium (Ti), alloys thereof, and/or the like. For example, the remaining first wiring layers 112 except for the uppermost first wiring layer M1, and the plurality of second wiring layers 122 may each include chemical copper formed by electroless plating, as a seed layer, and may include electrolytic copper formed based on the chemical copper by electrolytic plating, as a pattern plating layer. Meanwhile, as the seed layer, a titanium (Ti) layer and a copper (Cu) layer formed by sputtering may be included. Meanwhile, the uppermost first wiring layer M1 may not include a separate seed layer and may include an electrolytic copper formed by electrolytic plating as a pattern plating layer. The plurality of first and second wiring layers 112 and 122 may respectively perform various functions according to the design. For example, the plurality of first and second wiring layers 112 and 122 may each include wirings for signal transmission, wirings for power transmission, wirings for ground transmission, and the like. Meanwhile, these wirings may have various pattern forms such as lines, traces, planes, pads, and lands. If necessary, when the second insulating body 125 includes one or more second insulating layers 121, the second wiring portion 120 may include one or more second wiring layers 122 instead of multiple second wiring layers 122.

The plurality of first and second via layers 113 and 123 may each include a metal. The metal may include copper (Cu), aluminum (Al), silver (Ag), tin (Sn), gold (Au), nickel (Ni), lead (Pb), titanium (Ti), alloys thereof, and/or the like. For example, the plurality of first and second via layers 113 and 123 may each include chemical copper formed by electroless plating, as a seed layer, and may include electrolytic copper formed based thereon by electrolytic plating, as a pattern plating layer. Meanwhile, the seed layer may include a titanium (Ti) layer and a copper (Cu) layer formed by sputtering. The plurality of first and second via layers 113 and 123 may perform various functions according to the design. For example, the plurality of first and second via layers 113 and 123 may each include signal transmission vias, power transmission vias, ground transmission vias, and the like. The first and second connection vias included in the plurality of first and second via layers 113 and 123 respectively may be in plural. The first and second connection vias included in the plurality of first and second via layers 113 and 123, respectively, may have a filled and plated via structure, but are not limited thereto, and may have a conformal-plated via structure. If necessary, when the second insulating body 125 includes one or more second insulating layers 121, the second wiring portion 120 may include one or more second via layers 123 instead of the plurality of second via layers 123.

The first and second passivation layers 161 and 162 may each include an organic insulating material. The organic insulating material may include a thermosetting resin such as an epoxy resin, a thermoplastic resin such as a polyimide, or an inorganic filler and/or an organic filler together with a resin. For example, the organic insulating material may be, but is not limited to, Ajinomoto build-up film (ABF), a photoimageable dielectric material (PID), a solder resist (SR), or the like. The wiring patterns respectively exposed through the plurality of first openings h1 of the first passivation layer 161 may be the Solder Mask Defined (SMD) and/or Non-Solder Mask Defined (NSMD) type. One second opening h2 of the second passivation layer 162 may be a through cavity structure, but may also be a blind cavity structure that covers a portion of side surfaces of the exposed wiring patterns, if necessary.

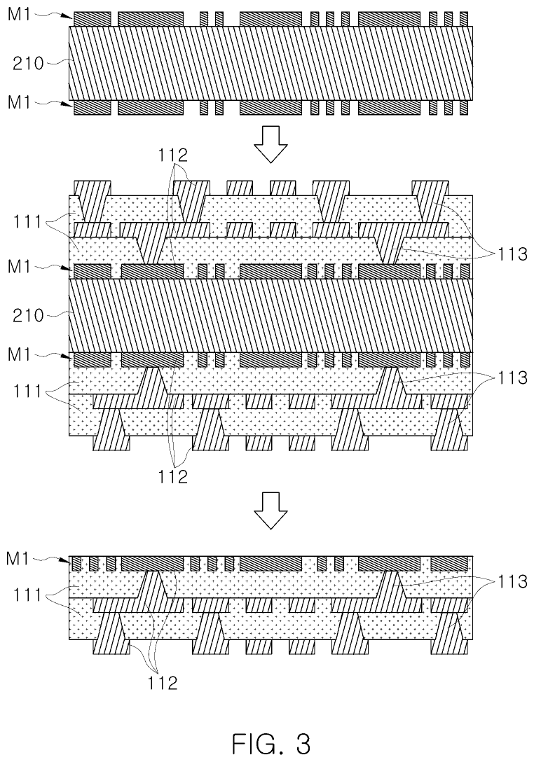

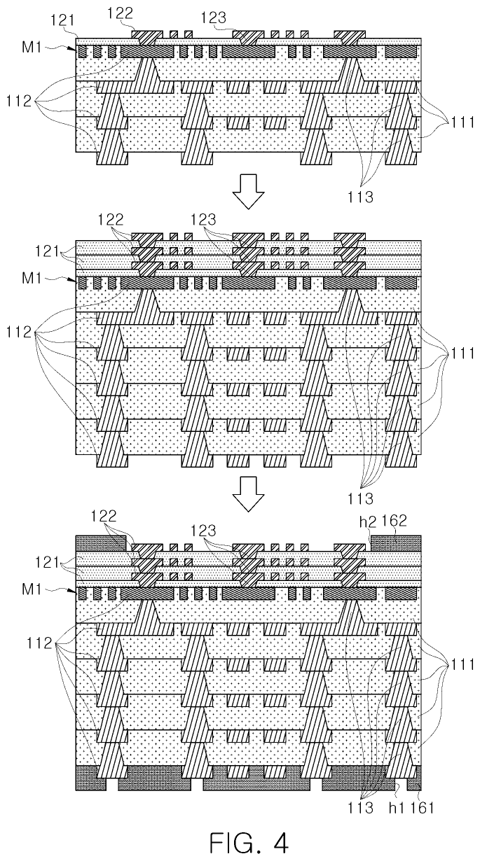

FIG. 3 and FIG. 4 are process cross-sectional views schematically illustrating an example of manufacturing a printed circuit board of FIG. 2.

Referring to FIG. 3, a first wiring layer M1 may be formed on a detach core 210. For example, a first wiring layer M1 that may include a microcircuit, for example, an ETS pattern, may be formed on a copper foil of the detach core 210 by a lithography process and a plating process. Next, two layers of first insulating layers 111, two layers of first wiring layers 112, and two layers of first via layers 113 may be formed on the detach core 210 by a build-up process. The build-up process may be performed by repeating lamination of an appropriate insulating material, formation of a via hole using a UV laser process or the like, a plating process, and the like. Next, the intermediate of the first wiring portion 110 manufactured as above may be separated from the detach core 210. After the detachment, the copper foil of the detach core 210 remaining in the intermediate of the first wiring portion 110 described above may be removed by etching, and at this time, if necessary, a recess step may be formed in the first wiring layer M1. Alternatively, a barrier layer such as a nickel layer may be further formed on the copper foil in advance so that a recess step does not occur in the first wiring layer M1. Meanwhile, the above-described process may be performed simultaneously on both sides of the detach core 210, and in this case, the intermediate of the first wiring portion 110 described above may be manufactured in plural after the detachment.

Referring to FIG. 4, a second insulation layer 121, a second wiring layer 122, and a second via layer 123 may be formed on a substantially flat surface of a first insulation layer 111 on which a first wiring layer M1 of an intermediate body of the first wiring portion 110 described above is exposed, by a build-up process. In addition, a first insulation layer 111, a first wiring layer 112, and a first via layer 113 may be formed on the opposite side by a build-up process. For example, a build-up process may be performed on both sides. Therefore, the second wiring layer 122 may be formed at a higher density through a microcircuit process. In addition, a multilayer substrate structure in a coreless form may be easily implemented. Therefore, the total package thickness may be reduced by reducing the number of layers, and it may easily respond to high-layering and large-area expansion. Accordingly, since die-to-die connection becomes possible at the substrate level, process difficulty, cost, and the like may be reduced. Meanwhile, the build-up process may be a process of repeating lamination of an appropriate insulating material, formation of a via hole using UV laser processing or the like, a plating process, and the like. Next, the build-up process may be further performed on both sides as required. Through this build-up process, the first wiring portion 110 and the second wiring portion 120 may be formed. Meanwhile, the build-up process may be a process of repeating lamination of an appropriate insulating material, formation of a via hole using UV laser processing or the like, a plating process, and the like. Next, first and second passivation layers 161 and 162 may be formed on the first and second wiring portions 110 and 120, respectively, as required, and a plurality of first openings h1 and one second opening h2 may be formed in the first and second passivation layers 161 and 162, respectively. The first and second passivation layers 161 and 162 may be formed by using a coating of an appropriate insulating material, lamination, and the like. The plurality of first openings h1 and one second opening h2 may be formed by photolithography or laser processing, depending on the material of the first and second passivation layers 161 and 162.

A printed circuit board 100 according to the above-described example may be manufactured through a series of processes, and for other aspects, the above-described content may be substantially identically applied thereto.

As set forth above, among the various effects of the present disclosure, one effect is that a printed circuit board that is easy to form a microcircuit may be provided by securing excellent flatness, and the like.

In addition, a printed circuit board having a multilayer substrate structure of a coreless type may be provided.

In addition, a printed circuit board in which costs may be reduced may be provided.

In the present disclosure, the expression “covering” may include a case of covering at least a portion as well as a case of covering the whole, and may also include a case of directly covering as well as a case of indirectly covering. In addition, the expression “filling” may include not only a case of completely filling, but also a case of at least partially filling, and may also include a case of approximately filling, and for example, may include a case where some gaps or voids are present. In addition, the expression “surrounding” may include not only the case of completely surrounding, but also the case of partially surrounding and the case of roughly surrounding. In addition, “exposing” may include not only the case of completely exposing, but also the case of partially exposing, and “exposing” may mean exposing from embedding the corresponding configuration. For example, exposing the pad by the opening may mean exposing the pad from the resist layer, and a surface treatment layer or the like may be further disposed on the exposed pad.

In the present disclosure, it may be determined by including process errors, positional deviations, measurement errors, or the like that occur in the manufacturing process. For example, being substantially coplanar may include not only a case where it is completely coplanar, but also a case where it is approximately coplanar. In addition, having a substantially specific shape may include not only a case where it has completely such a shape, but also a case where it has approximately such a shape. In addition, substantially the same insulating material may mean not only a case where it is a completely identical insulating material, but also a case where it includes an insulating material of the same type. Accordingly, the composition of the insulating material may be substantially the same, but the detailed composition ratio thereof may be slightly different.

In the present disclosure, the meaning of cross-section may mean a cross-sectional shape when the object is substantially vertically cut, or a cross-sectional shape when the object is viewed from a side-view. In addition, the meaning of “on a plane” may mean a plane shape when the object is horizontally cut, or a plane shape when the object is viewed from a top-view or bottom-view.

In the present disclosure, lower side, lower portion, lower surface, and the like are used to mean a downward direction based on the cross section of the drawing for convenience, and upper side, upper portion, upper surface, and the like are used to mean the opposite direction. However, this is to define the direction for convenience of description, and the scope of the claims is not particularly limited by the description of this direction, of course, and the concept of upper and lower may change at any time.

In the present disclosure, the meaning of being connected is a concept including not only being directly connected but also being indirectly connected through an adhesive layer or the like. In addition, the meaning of being electrically connected is a concept including both physically connected and electrically coupled cases. In addition, expressions such as first, second and the like are used to distinguish one component from another, and do not limit the order and/or importance of the components. In some cases, without departing from the scope of rights, the first element may be named a second element, and similarly, the second element may be referred to as the first element.

In the present disclosure, thickness, width, length, depth, linewidth, spacing, pitch, separation distance, surface roughness, and the like may be measured using a scanning microscope, an optical microscope, or the like, based on a cross-section of a polished or cut printed circuit board, respectively. The cut cross-section may be a vertical cross-section or a horizontal cross-section, and each value may be measured based on a required cut cross-section. For example, the width of the upper end portion and/or the lower end portion of a via may be measured on a cross-section cut along the central axis of the via. Meanwhile, in cases where the measured value is not constant, the value may be determined as an average value of values measured at five arbitrary points.

The expression “an (one) example” used in the present disclosure does not mean the same embodiments, and is provided to emphasize and describe different unique characteristics. However, the examples presented above are not excluded from being implemented in combination with features of other examples. For example, even if a matter described in a specific example is not described in another example, it may be understood as a description related to another example, unless there is a description contrary to or contradictory to the matter in the other example.

Terms used in this disclosure are only used to describe an example, and are not intended to limit the disclosure. In this case, singular expressions include plural expressions unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
a first wiring portion including a first insulating body and a plurality of first wiring layers respectively disposed on a lower surface of or within the first insulating body, an uppermost first wiring layer of the plurality of first wiring layers being embedded in an upper side of the first insulating body, and at least a portion of an upper surface of the uppermost first wiring layer being exposed from an upper surface of the first insulating body; and
a second wiring portion disposed on an upper side of the first wiring portion, and including a second insulating body covering at least a portion of the upper surface of the uppermost first wiring layer, and a plurality of second wiring layers respectively disposed on an upper surface of or within the second insulating body,
wherein a minimum pitch of a wiring included in at least one of the plurality of second wiring layers is smaller than a minimum pitch of a wiring included in at least one of remaining first wiring layers excluding the uppermost first wiring layer.

2. The printed circuit board of claim 1, wherein a minimum pitch of a wiring included in each of the plurality of second wiring layers is smaller than a minimum pitch of a wiring included in each of the remaining first wiring layers.

3. The printed circuit board of claim 2, wherein a minimum pitch of a wiring included in the uppermost first wiring layer is smaller than a minimum pitch of the wiring included in each of the remaining first wiring layers.

4. The printed circuit board of claim 1, wherein a minimum linewidth of a wiring and a minimum spacing between wirings included in at least one of the plurality of second wiring layers are smaller than a minimum linewidth of a wiring and a minimum spacing between wirings included in at least one of the remaining first wiring layers.

5. The printed circuit board of claim 4, wherein a minimum linewidth of a wiring and a minimum spacing between wirings included in each of the plurality of second wiring layers are smaller than a minimum linewidth of a wiring and a minimum spacing between wirings included in each of the remaining first wiring layers.

6. The printed circuit board of claim 5, wherein a minimum linewidth of a wiring and a minimum spacing between wirings included in the uppermost first wiring layer are smaller than the minimum linewidth of the wiring and the minimum spacing between the wirings included in each of the remaining first wiring layers.

7. The printed circuit board of claim 1, wherein a minimum insulation distance between the plurality of second wiring layers is smaller than a minimum insulation distance between the plurality of first wiring layers.

8. The printed circuit board of claim 7, wherein a thickness of the second insulating body is less than a thickness of the first insulating body.

9. The printed circuit board of claim 1, wherein the first wiring portion further includes a plurality of first via layers respectively disposed within the first insulating body and electrically connecting the plurality of first wiring layers to each other, and
the second wiring portion further includes a plurality of second via layers respectively disposed within the second insulating body and electrically connecting the plurality of second wiring layers to each other,
wherein a lowermost second via layer among the plurality of second via layers electrically connects the uppermost first wiring layer and a lowermost second wiring layer among the plurality of second wiring layers.

10. The printed circuit board of claim 9, wherein a first connection via included in each of the plurality of first via layers has a substantially tapered side surface of which a width of a lower end portion is wider than a width of an upper end portion thereof in a cross-section, and
a second connection via included in each of the plurality of second via layers has a substantially tapered side surface of which a width of an upper end portion is wider than a width of a lower end portion thereof in a cross-section.

11. The printed circuit board of claim 1, further comprising:
a first passivation layer disposed on the lower surface of the first insulating body and having a plurality of first openings respectively exposing at least a portion of a lowermost first wiring layer among the plurality of first wiring layers; and
a second passivation layer disposed on the upper surface of the second insulating body and having a second opening exposing at least a portion of an uppermost second wiring layer among the plurality of second wiring layers.

12. The printed circuit board of claim 11, wherein the plurality of first openings exposes at least portions of a plurality of wiring patterns included in the lowermost first wiring layer, respectively, and
the second opening exposes at least portions of a plurality of wiring patterns included in the uppermost second wiring layer.

13. A printed circuit board comprising:
a first wiring portion including a plurality of first insulating layers, a plurality of first wiring layers, and a plurality of first via layers, an uppermost first wiring layer of the plurality of first wiring layers being embedded in an upper side of an uppermost first insulating layer of the plurality of first insulating layers, and at least a portion of an upper surface of the uppermost first wiring layer being exposed from an upper surface of the uppermost first insulating layer; and
a second wiring portion disposed on an upper side of the first wiring portion, and including one or more second insulating layers, one or more second wiring layers, and one or more second via layers,
wherein a first connection via included in each of the plurality of first via layers and a second connection via included in each of the one or more second via layers have side surfaces substantially tapered in opposite directions in a cross-section.

14. The printed circuit board of claim 13, wherein the first connection via included in each of the plurality of first via layers has a substantially tapered side surface of which a width of a lower end portion is greater than a width of an upper end portion thereof in a cross-section, and
the second connection via included in each of the one or more second via layers has a substantially tapered side surface of which a width of an upper end portion is greater than a width of a lower end portion thereof in a cross-section.

15. The printed circuit board of claim 13, wherein a lowermost second insulating layer among the one or more second insulating layers covers at least a portion of the upper surface of the uppermost first wiring layer, and
the plurality of first wiring layers and the one or more second wiring layers are electrically connected to each other through the plurality of first via layers and the one or more second via layers.

16. The printed circuit board of claim 13, wherein the first and second wiring portions each have a coreless substrate structure.

17. The printed circuit board of claim 13, wherein the uppermost first wiring layer comprises an Embedded Trace Substrate (ETS) pattern embedded in a first insulating body and exposed from an upper surface of the first insulating body.

18. The printed circuit board of claim 17, wherein an upper surface of the ETS pattern supports the second wiring portion and has a substantially flat base.
